(19) United States
(12) Patent Application Publication
(10) Pub. No.: US 2011/0050286 A1
(43) Pub. Date: Mar. 3, 2011

(54) TEMPERATURE SENSING CIRCUIT

(75) Inventor: Jong Ho SON, Seoul (KR)

(73) Assignee: HYNIX SEMICONDUCTOR INC., Gyeonggi-do (KR)

(21) Appl. No.: 12/647,817

(22) Filed: Dec. 28, 2009

(30) Foreign Application Priority Data
Aug. 28, 2009 (KR) 10-2009-0080735

(51) Int. Cl. H03K 5/22

(52) U.S. Cl. 327/72

(57) ABSTRACT

A temperature sensing circuit that does not use an oscillator is presented. The temperature sensing circuit includes a selector and a detector. The selector is configured to select and output a reference voltage from first and second level signals in response to first and second trimming signals. The first and second level signals are relatively insensitive to temperature variations. The detector is configured to generate a detection voltage by comparing the reference voltage with a variable voltage depending on internal temperature.

### CROSS-REFERENCES TO RELATED PATENT APPLICATION

The present application claims priority under 35 U.S.C 119(a) to Korean Application No. 10-2009-0080735, filed on Aug. 28, 2009, in the Korean Intellectual Property Office, which is incorporated herein by reference in its entirety as set forth in full.

### BACKGROUND

This disclosure relates to temperature sensing circuits with improved reliability.

Driven by the ever-growing demands for higher performance of electronic systems, such as, personal computers, and communication apparatuses, semiconductor memories are steadily evolving to have higher frequency operations and integration densities. These semiconductor memories may include dynamic random access memories (DRAMs) employed as storage units in the systems. Other types of semiconductor memories which are embedded in portable systems that operate via battery power, such as cellular phones or laptop computers, are especially require lower power consumption. For the low power requirement, a number of studies have been ongoing and have succeeded in dropping the dissipation rates of operating and standby currents flowing through semiconductor memories employed in these types of portable systems.

In the meantime, the data retention characteristics of DRAM cells, each of which is formed of one transistor and one capacitor, are very sensitive to temperature. So it may be necessary to adjust operating conditions of circuit elements or blocks in semiconductor integrated circuits in accordance to their working temperature variations. For instance, refresh periods of DRAMs used in mobile products are adjusted depending on variation of their working temperatures.

Several kinds of temperature sensors, e.g., digital temperature sensor regulator (DTSR), and analog temperature sensor regulator (ATSR), can be used to adjust the operating conditions of these devices. Generally temperature sensors operate by detecting current and knowing a relationship between temperature, the operating conditions can be internally adjusted. For instance, self-refresh periods can be controlled to reduce current dissipation in self-refresh modes and in normal modes by monitoring peripheral temperature.

Traditional temperature sensors normally use an oscillator to generate a reference period signal having an uniform cycle and a comparative period signal having a cycle which becomes longer as a function of a temperature drop. These traditional temperature sensors are used to detect internal temperatures of its corresponding semiconductor apparatus by comparing the reference period signal with the comparative period signal during every predetermined time period. Since a cycle of the reference period signal generated from the oscillator easily varies by variations of pressure, voltage and temperature (referred to as ‘PVT variations’), then these traditional temperature sensors are sometimes inadequate in assuring the accuracy of the measured internal temperature. Further, increasing the number of the reference period signals for enhancing the fineness of internal temperature detection may cause a layout area of the circuit (i.e., oscillator) generating the reference period signal.

### SUMMARY

Accordingly, exemplary embodiments are directed to an temperature sensing circuit capable of improving the accuracy of finding out internal temperature, by detecting the internal temperature in a function of voltage, without an oscillator.

In exemplary embodiments, a temperature sensing circuit may include a selector configured to select and output a reference voltage from first and second level signals, which have uniform voltage levels, in response to first and second trimming signals, and a detector configured to generate a detection voltage by comparing the reference voltage with a variable voltage depending on internal temperature.

In exemplary embodiments, a temperature sensing circuit may include a variable voltage generator configured to a variable voltage depending on internal temperature, a level signal generator configured to a plurality of level signals by dividing a power source voltage, a trimming signal generator configured to generate a trimming signal in response to a test mode signal, a selector configured to select and output a reference voltage from the level signals in response to the trimming signal, and a detector configured to generate a detection voltage by comparing the variable voltage with the reference voltage.

A further understanding of the nature and advantages of the present invention herein may be realized by reference to the remaining portions of the specification and the attached drawings.

### BRIEF DESCRIPTION OF THE DRAWINGS

The above and other aspects, features and other advantages will be more clearly understood from the following detailed description taken in conjunction with the accompanying drawings, in which:

FIG. 1 is a block diagram illustrating an organization of a temperature sensing circuit according to exemplary embodiments of the present invention;

FIG. 2 is a circuit diagram illustrating the variable voltage generator included in the temperature sensing circuit of FIG. 1;

FIG. 3 is a circuit diagram illustrating the level signal generator included in the temperature sensing circuit of FIG. 1;

FIG. 4 is a circuit diagram illustrating the trimming signal generator included in the temperature sensing circuit of FIG. 1;

FIG. 5 is a circuit diagram illustrating the first selector included in the temperature sensing circuit of FIG. 1;

FIG. 6 is a circuit diagram illustrating the first detector included in the temperature sensing circuit of FIG. 1;

FIG. 7 is a graphic diagram plotting an operational feature of the temperature sensing circuit shown in FIG. 1.

### DESCRIPTION OF EMBODIMENTS

Hereinafter, various exemplary embodiments will now be described more fully with reference to the accompanying drawings in which some exemplary embodiments are shown. However, specific structural and functional details disclosed herein are merely representative for purposes of describing exemplary embodiments of the present invention. Like numbers refer to like elements throughout the description of the drawings.

The terminology used herein is for the purpose of describing particular embodiments only and is not intended to be limiting of exemplary embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Further, it will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the invention. As used herein, the term “and/or” includes any and all combinations of one or more of the associated listed items. Also will be understood that when an element is referred to as being “connected” or “coupled” to another element, it can be directly connected or coupled to the other element or intervening elements may be present.

In order to more specifically describe exemplary embodiments, various aspects will be hereinafter described in detail with reference to the attached drawings.

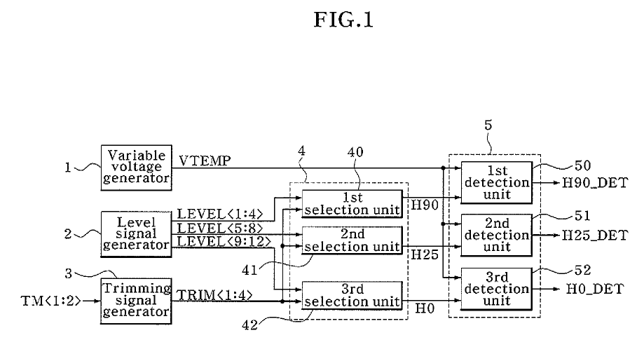

FIG. 1 illustrates an organization of a temperature sensing circuit according to exemplary embodiments of the present invention.

Referring to FIG. 1, the temperature sensing circuit may be comprise a variable voltage generator 1, a level signal generator 2, a trimming signal generator 3, a selector 4 and a detector 5.

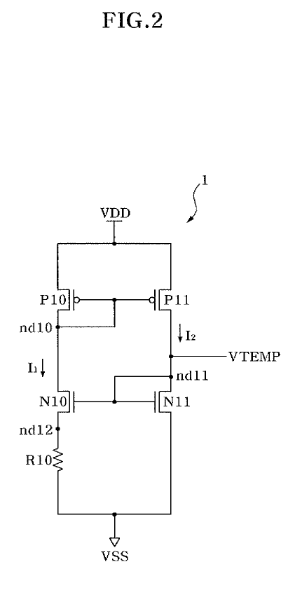

One preferred embodiment of the variable voltage generator 1, as illustrated in FIG. 2, is exemplarily composed of a PMOS transistor P10, a PMOS transistor P11, an NMOS transistor N10, an NMOS transistor N11, and a resistor R10. The PMOS transistor P10 is configured to be coupled between the power source voltage terminal VDD and a node nd10 and configured to be turned on responding to a voltage of the node nd10. The PMOS transistor P11 is configured to be coupled between the power source voltage terminal VDD and a node nd11, from which a variable voltage VTEMP is output, and configured to be turned on responding to a voltage of the node nd11. The NMOS transistor N10 is configured to be coupled between the node nd10 and a node n12 and configured to be turned on responding to the voltage of the node nd11. The NMOS transistor N11 is configured to be coupled between the node nd11 and the ground voltage terminal VSS and configured to be turned on responding to the voltage of the node nd11. The resistor R10 is configured to be coupled between the node nd11 and the ground voltage terminal VSS. With this structural configuration the PMOS transistor P10, the PMOS transistor P11, the NMOS transistor N10 and the NMOS transistor N11 of the variable voltage generator 1 constitutes a current mirror.

With this structure, the variable voltage VTEMP generated from the variable voltage generator 1 is given by

$$VTEMP = {V}_{th} + \frac{2}{R μ {C}_{ox} \sqrt{\frac{W 2}{L 2}}} [ \frac{1}{\sqrt{\frac{W 2}{L 2}}} - \frac{1}{\sqrt{\frac{W 1}{L 1}}} ] \qquad [ Equation 1 ]$$

Equation 1 can be derived from the characteristics such that currents flowing through the NMOS transistors N10 and N11 of the current mirror are substantially equal each other (I₁=I₂) and voltages of the nodes nd10 and nd11 are also substantially equal each other. In Equation 1, Vₜₕ is the threshold voltage of the NMOS transistors N10 and N11 and Cₒₓ is a constant determined by the characteristics of NMOS transistors N10 and N11. W1 and L1 denote a width and a length of the NMOS transistor N10. W2 and L2 denote a width and a length of the NMOS transistor N11. And R corresponds to the resistance of the resistor R10. As the temperature drops, then Vₜₕ elevates and R and μ (carrier mobility) become smaller. Thus, the variable voltage VTEMP rises up along a drop in temperature. That is, the variable voltage VTEMP has the characteristics of being inversely linear in proportion to the temperature.

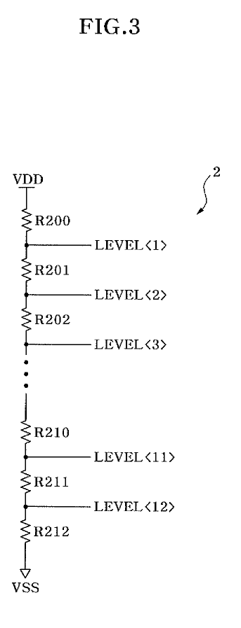

Referring to FIG. 3, the level signal generator 2 is exemplarily composed of a plurality of resistors R200˜R212 serially coupled together and between the power source voltage terminal VDD and the ground voltage terminal VSS. The level signal generator 2 divides the power source voltage VDD to generate first through twelfth level signals LEVEL<1:12>. Although the resistors R200˜R212 increases in resistance along temperature, the magnitude of the resistors R200˜R212 is preferably smaller than that of the turn-on resistance of the NMOS transistor. Therefore, the voltage levels of the first through twelfth level signals LEVEL<1:12> are substantially maintained as relatively constant, in which the first level signal LEVEL<1> is the largest in voltage level while the twelfth level signal LEVEL<12> is the smallest.

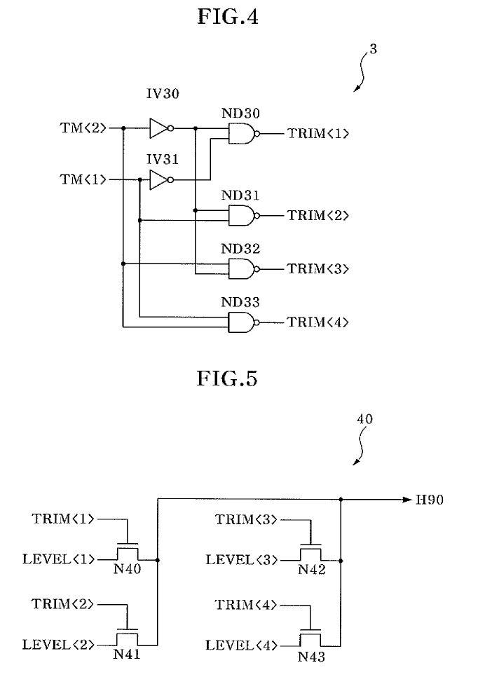

Referring to FIG. 4, the trimming signal generator 3 decodes first and second test mode signals TM<1:2> and generates first through fourth trimming signals TRIM<1:4>. According to a level combination of the first and second test mode signals TM<1:2>, one of the first through fourth trimming signals TRIM<1:4> is activated as summarized in Table 1.

TABLE 1

| TM<2> | TM<1> | TRIM<1> | TRIM<2> | TRIM<3> | TRIM<4> |
|---|---|---|---|---|---|
| L | L | H | L | L | L |
| L | H | L | H | L | L |
| H | L | L | L | H | L |
| H | H | L | L | L | H |

The selector 4, as shown in FIG. 1, is organized as a first selection unit 40, a second selection unit 41 and a third selection unit 42. Referring to FIG. 5, the first selection unit is exemplarily composed of an NMOS transistor N40, an NMOS transistor N41, an NMOS transistor N42, and an NMOS transistor N43. The NMOS transistor N40 is configured to function as a switch for transferring the first level signal LEVEL<1> to a first reference voltage H90 in response to the first trimming signal TRIM<1>. The NMOS transistor N41 is configured to function as a switch for transferring the second level signal LEVEL<2> to the first reference voltage H90 in response to the second trimming signal TRIM<2>. The NMOS transistor N42 is configured to function as a switch for transferring the third level signal LEVEL<3> to the first reference voltage H90 in response to the third trimming signal TRIM<3>. The NMOS transistor N43 is configured to function as a switch for transferring the fourth level signal LEVEL<4> to the first reference voltage H90 in response to the fourth trimming signal TRIM<4>. The second selection unit 41 is configured to selectively output one of the fifth through eighth level signals LEVEL<5:8> as a second reference voltage H25 in response to the first through fourth trimming signals TRIM<1:4>. The third selection unit 42 is configured to selectively output one of the ninth through twelfth level signals LEVEL<9:12> as a third reference voltage H0 in response to the first through fourth trimming signals TRIM<1:4>. The second and third selection units, 41 and 42, are substantially same as the first selection unit in structure, so those structural features will not be further described.

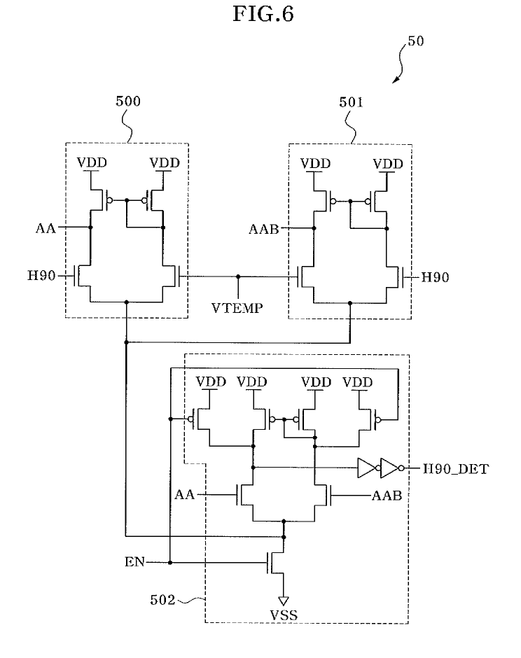

The detector 5, as illustrated in FIG. 1, is organized of a first detection unit 50, a second detection unit 51 and a third detection unit 52. Referring to FIG. 6, the first detection unit 50 is exemplarily composed of a first comparator 500, a second comparator 501, and a differential amplifier 502. The first comparator 500 is configured to generate a comparison signal AA by comparing the variable voltage VTEMP with the first reference voltage H90. The second comparator 501 is configured to generate an inverted comparison signal AAB by comparing the variable voltage VTEMP with the first reference voltage H90. The differential amplifier 502 is configured to generate a first detection voltage H90_DET by differentially amplifying the comparison signal AA and the inverted comparison signal AAB. In this exemplary embodiment, when internal temperature is over 90° C., then the variable voltage VTEMP is generated in a level lower than the first reference voltage H90. As a result, the first comparator 500 generates the comparison signal AA of low level and the second comparator 501 generates the inverted comparison signal AAB of high level. The differential amplifier 502 then generates the first detection voltage H90_DET at a high level. On the other hand, if internal temperature is below 90° C., then the variable voltage VTEMP is generated at a level higher than the first reference voltage H90. In this case, the comparison signal AA and the inverted comparison signal AAB are generated in high and low levels, respectively, to output the first detection voltage H90_DET of low level from the differential amplifier 502.

The second and third detection units, 51 and 52, are substantially the same as that of the first detection unit 50 in configuration, except that the second detection unit 51 generates a second detection voltage H25_DET by comparing the variable voltage VTEMP with the second reference voltage H25 and the third detection unit 52 generates a third detection voltage H0_DET by comparing the variable voltage VTEMP with the third reference voltage H0.

Now an operation of the temperature sensing circuit will be described hereinafter in conjunction with FIGS. 1 through 6.

First, the variable voltage generator 1 operates to generate the variable voltage VTEMP depending on the internal temperature of the semiconductor memory apparatus. As aforementioned, the variable voltage VTEMP provided from the variable voltage generator VTEMP linearly varies in inverse proportion to temperature. That is, the variable voltage VTEMP decreases as the temperature rises, and increases as the temperature drops.

Meanwhile, the level signal generator 2 is configured to provide the first through twelfth level signals LEVEL<1:12> by dividing the power source voltage VDD and the trimming signal generator 3 provides the first through fourth trimming signals TRIM<1:4> by decoding the first and second test mode signals TM<1:2>. The selector 4 is configured to generate the first through third reference voltages H90, H25 and H0 from the first through twelfth level signals LEVEL<1:12> in response to the first through fourth trimming signals TRIM<1:4>. Hereinafter, an operation of the selector 4 will be described assuming that the first test mode signal TM<1> is generated at a high level and the second test mode signal TM<2> is generated at a low level.

If the first test mode signal TM<1> is set at a high level and the second test mode signal TM<2> is set on a low level, then the second trimming signal TRIM<2> of the first through fourth trimming signals TRIM<1:4> is activated alone as a high level. Then, the first selection unit 40 is configured to output the first reference voltage H90 by selecting the second level signal LEVEL<2> from the first through fourth level signals LEVEL<1:4>. The second selection unit 41 is configured to output the second reference voltage H25 by selecting the sixth level signal LEVEL<6> from the fifth through eighth level signals LEVEL<5:8>. The third selection unit 42 is configured to output the third reference voltage H0 by selecting the tenth level signal LEVEL<10> from the ninth through twelfth level signals LEVEL<1:4>.

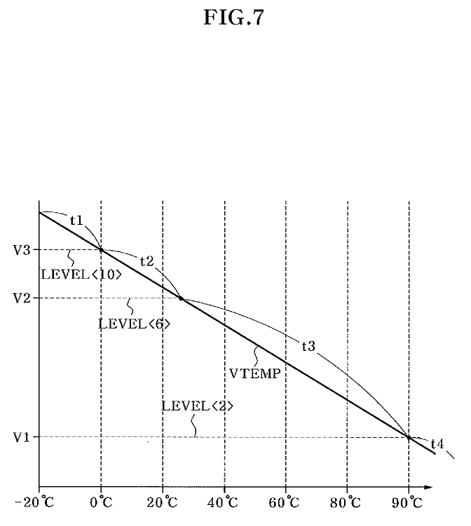

Next, the detector 5 is configured to generate the first detection voltage H90_DET, the second detection voltage H25_DET and the third detection voltage H0_DET in response to the variable voltage VTEMP and the first through third reference voltage H90, H25 and H0. Internal temperature of the semiconductor memory apparatus can be measured by using levels of the first detection voltage H90_DET, the second detection voltage H25_DET and the third detection voltage H0_DET. For instance, in case of selecting the second level signal LEVEL<2> to output the first reference voltage H90, selecting the sixth level signal LEVEL<6> to output the second reference voltage H25, and selecting the tenth level signal LEVEL<10> to output the third reference voltage H0, the detector 5 operates as follows as shown in FIG. 7.

In a period t1 when the internal temperature of the semiconductor memory apparatus is below 0° C., the variable voltage VTEMP is generated at a level higher than a voltage level V3 of the tenth level signal LEVEL<10>. As the variable voltage VTEMP is higher than the first through third reference voltages H90, H25 and H0, the detector 5 is configured to generate the first detection voltage H90_DET, the second detection voltage H25_DET and the third detection voltage H0_DET all at low levels.

In a period t2 where the internal temperature of the semiconductor memory apparatus is above 0° C. but below 25° C., then the variable voltage VTEMP is generated in a level lower than the voltage level V3 of the tenth level signal LEVEL<10> but higher than a voltage level V2 of the sixth level signal LEVEL<6>. As the variable voltage VTEMP is higher than the first through second reference voltages H90 and H25 but lower than the third reference voltage H0, then the detector 5 is configured to generate the first and second detection voltages H90_DET and H25_DET at low levels and generates the third detection voltage H0_DET at a high level.

In a period t3 when internal temperature of the semiconductor memory apparatus is above 25° C. but below 90° C., the variable voltage VTEMP is generated at a level lower than the voltage level V2 of the sixth level signal LEVEL<6> but higher than a voltage level V1 of the second level signal LEVEL<2>. Since the variable voltage VTEMP is higher than the first reference voltage H90 but lower than the second and third reference voltages H25 and H0, then the detector 5 is configured to generate the first detection voltage H90_DET at a low level and is configured to generate the second and third detection voltages H25_DET and H0_DET at high levels.

In a period t4 where the internal temperature of the semiconductor memory apparatus is above 90° C., the variable voltage VTEMP is generated at a level lower than the voltage level V1 of the second level signal LEVEL<2>. As the variable voltage VTEMP is lower than the first through third reference voltages H90, H25 and H0, then the detector 5 is configured to generate the first through third detection voltages H90_DET, H25_DET and H0_DET all at high levels.

As described above, the temperature sensing circuit according to exemplary embodiments is configured to generate, without an oscillator, a variable voltage VTEMP, which is linearly inversely proportional to the temperature, and to generate the first through third reference voltages H90, H25 and H0 which are relatively constant with respect to the temperature. The temperature sensing circuit according to exemplary embodiments is also configured to determine the levels of the first through third detection voltages H90_DET, H25_DET and H0_DET by comparing the variable voltage VTEMP with the first through third reference voltages H90, H25 and H0. From the levels of the first detection voltage H90_DET, the second detection voltage H25_DET and the third detection voltage H0_DET, it is possible to identify which one of the periods t1˜t4 corresponds to the internal temperature of the semiconductor memory apparatus.

Summarily, in the aforementioned embodiment, the temperature sensing circuit is able to detect internal temperature of the semiconductor memory apparatus in fineness, finding out a corresponding one of four temperature periods to which the internal temperature belongs, by using three detection voltages generated from three reference voltages. In exemplary embodiments of the present invention, the number of the reference voltages and the trimming voltages may be increased. As many as the number of the reference voltages and the trimming signals, the number of the detection voltages may be larger so much to enhance the accuracy of sensing internal temperature of the semiconductor memory apparatus, but restrictive in considering a circuit area.

The foregoing is illustrative of exemplary embodiments and is not to be construed as limiting thereof. Although a few exemplary embodiments have been described, those skilled in the art will readily appreciate that many modifications are possible in exemplary embodiments without materially departing from the novel teachings and advantages. Accordingly, all such modifications are intended to be included within the scope of this invention as defined in the claims.

What is claimed is:

1. A temperature sensing circuit, comprising:
a selector configured to select and output a reference voltage from first and second level signals in response to first and second trimming signals, wherein the first and second level signals have substantially invariant voltage levels as a function of temperature; and
a detector configured to generate a detection voltage by comparing the reference voltage against a variable voltage, wherein the variable voltage is dependent on internal temperature.

2. The temperature sensing circuit according to claim 1, wherein the selector comprises:
a first switch configured to output the first level signal in response to the first trimming signal; and
a second switch configured to output the second level signal in response to the second trimming signal.

3. The temperature sensing circuit according to claim 1, wherein the variable voltage decreases as the internal temperature increases.

4. The temperature sensing circuit according to claim 1, wherein the detection voltage is generated at a first level when the variable voltage is higher than the reference voltage, and the detection voltage is generated at a second level when the variable voltage is lower than the reference voltage.

5. The temperature sensing circuit according to claim 1, wherein the detector comprises:
a first comparator configured to generate a comparison signal by comparing the variable voltage with the reference voltage;
a second comparator configured to generate an inverted comparison signal by comparing the variable voltage with the reference voltage; and
a differential amplifier configured to generate the detection voltage by differentially amplifying the comparison signal and the inverted comparison signal.

6. A temperature sensing circuit, comprising:
a variable voltage generator configured generate to a variable voltage as a function of internal temperature;
a level signal generator configured to generate a plurality of level signals by dividing a power source voltage;
a trimming signal generator configured to generate a trimming signal in response to a test mode signal;
a selector configured to select and output a reference voltage from the level signals in response to the trimming signal; and
a detector configured to generate a detection voltage by comparing the variable voltage with the reference voltage.

7. The temperature sensing circuit according to claim 6, wherein the variable voltage generated from the variable voltage generator decreases as the internal temperature increases.

8. The temperature sensing circuit according to claim 7, wherein the variable voltage generator comprises:
a first MOS transistor coupled between a power source voltage terminal and a first node and configured to be turned in response to a voltage of the first node;
a second MOS transistor coupled between the power source voltage terminal and a second node and configured to be turned on in response to the voltage of the first node;
a third MOS transistor coupled between the first node and a third node and configured to be turned on in response to a voltage of the second node;
a fourth MOS transistor coupled between the second node and a ground voltage terminal and configured to be turned on in response to the voltage of the second node; and
a resistor coupled between the third node and the ground voltage terminal.

9. The temperature sensing circuit according to claim 6, wherein the level signal generator comprises a resistor coupled between the power source voltage terminal and a ground voltage terminal.

10. The temperature sensing circuit according to claim 6, wherein the trimming signal generator configured to decode the test mode signal and to generate the trimming signal.

11. The temperature sensing circuit according to claim 6, wherein the selector comprises:
a first switch configured to output the reference voltage from a first one of the level signals; and
a second switch configured to output the reference voltage from a second one of the level signals.

12. The temperature sensing circuit according to claim 6, wherein the detection voltage is generated at a first level when the variable voltage is higher than the reference voltage, while the detection voltage is generated at a second level when the variable voltage is lower than the reference voltage.

13. The temperature sensing circuit according to claim 6, wherein the detector comprises:
a first comparator configured to generate a comparison signal by comparing the variable voltage with the reference voltage;
a second comparator configured to generate an inverted comparison signal by comparing the variable voltage with the reference voltage; and
a differential amplifier configured to the detection voltage by differentially amplifying the comparison signal and the inverted comparison signal.
